(19) United States
(12) Patent Application Publication
(10) Pub. No.: US 2009/0301760 A1
(43) Pub. Date: Dec. 10, 2009

(54) Method of Soldering a Module Board

(76) Inventors: Masato Shimamura, Saitama (JP); Ko Inaba, Tokyo (JP); Hiroshi Okada, Tochigi (JP); Tsukasa Ohnishi, Saitama (JP)

Correspondence Address: MICHAEL TOBIAS, 1629 K ST NW, SUITE 300, WASHINGTON, DC, 20006, US

(21) Appl. No.: 11/922,247

(22) PCT Filed: Jun. 13, 2006
(86) PCT No.: PCT/JP2006/311790

§ 371 Date: Jul. 8, 2009

(30) Foreign Application Priority Data
Jun. 16, 2005 (JP) 2005-175969

(51) Int. Cl. H05K 1/00; H05K 3/34

(52) U.S. Cl. 174/250; 29/830; 29/839; 29/840

(57) ABSTRACT

As BGA's and CSP's become widespread, the number of steps in soldering module boards to rigid printed wiring boards increases. A printed circuit board warps due to heating during reflow, so even if mounting is carried out at a temperature sufficiently exceeding the melting point of a solder alloy, there was a problem of the phenomenon of fusion defects in which the solder bumps of a module board of a CSP, a BGA, or the like and the mounting paste do not fuse or parts having leads and solder paste do not fuse, resulting in conduction defects.

Means for Solving the Problem

When soldering a module board to a rigid printed wiring board, a post-flux is applied to a module board before mounting, a solder paste is then applied to the rigid printed wiring board, and the module board is soldered.

### TECHNICAL FIELD

This invention relates to a soldering method using a lead-free solder alloy, which prevents the occurrence of defective connections due to fusion defects when performing mounting and connection by heating and melting of module boards on which are mounted packaged parts and particularly electronic parts without leads typified by BGA's and CSP's which have solder bumps.

### BACKGROUND ART

Module boards and rigid printed wiring boards are terms for electronic parts used in Survey of Dynamic Statistics on Production by the Ministry of Economy, Trade, and Industry of Japan. Rigid printed wiring boards contain various electronic parts to form electronic circuits. Usually there is only rigid printed wiring board per piece of equipment. They are also referred to as main boards. In contrast, a module board corresponds to a substrate of a single-chip part such as a BGA (ball grid array) or a CSP (chip size package) having bumps formed by solder balls, or to a substrate for a MCM (multi-chip module) having a large number of chips disposed thereon. Module boards are also referred to as sub-boards.

Packaged parts mounted on rigid printed wiring boards include parts without leads such as BGA's and CSP's as well as parts such as wafer bumps. Among these parts, parts without leads such as CSP's and BGA's (referred to below as BGA's and the like) usually have electrodes formed by solder bumps. Namely, with BGA's and the like, solder bumps are previously formed on the electrodes of a module board, and when the module board is mounted on a printed circuit board, the module board is made to contact the portions to be soldered of a rigid printed wiring board.

When heating takes place in a heating apparatus such as a reflow furnace, the solder bumps formed on the module board and the solder paste printed on the rigid printed wiring board melt and fuse, and the portions to be soldered of the module board and the rigid printed wiring board are soldered to each other and electrically connected.

Typical methods of forming solder bumps on a module board for a BGA or the like include use of solder balls or solder paste.

A conventional solder alloy for forming solder bumps was a Pb—Sn based solder alloy. A Pb—Sn based solder alloy was used as solder balls for forming solder bumps for the above-described BGA's and the like and for wafers. It was also much used in solder paste. This Pb—Sn based solder alloy has excellent solderability, so when a workpiece was soldered to a printed circuit board, soldering could be carried out with excellent reliability in that there was little occurrence of soldering defects.

When electronic equipment which is soldered with a Pb—Sn based solder alloy becomes old or malfunctions, it is almost always discarded. Among the structural materials of discarded electronic equipment, metal in frames, plastic in cases, glass in displays, and the like are recovered and reused. However, printed circuit boards cannot be reused, so they are often disposed of by burial. This is because in a printed circuit board, resin and copper foil are adhered to each other and solder is metallically bonded to the copper foil, so they cannot be separated from each other.

If a printed circuit board which has been disposed of by burial is contacted by acid rain which seeps into the ground, Pb in the solder is dissolved out by the acid rain, and acid rain containing Pb further seeps into the ground and mixes with underground water. It is thought that if underground water containing Pb is drunk for long periods by humans or livestock, Pb accumulates in the body and eventually causes lead poisoning. Therefore, the use of Pb has come to be regulated on a global scale, and so-called lead-free solder which does not contain Pb has come to be used.

Lead-free solder has Sn as a main component to which Ag, Bi, Cu, Sb, In, Ni, Zn, and the like are suitably added.

From in the past, lead-free solders included binary alloys having Sn as a main component such as Sn—Cu, Sn—Sb, Sn—Bi, Sn—Zn, and Sn—Ag as well as multiple-element lead-free solders in which other elements are added to these binary alloys. In general, Sn—Cu and Sn—Sb lead-free solders have a high melting point. As a result, under the same conditions, they are much inferior to conventional Pb—Sn solders with respect to solderability.

Sn—Bi based solders become brittle and if an impact is imparted to soldered portions, they easily break. Furthermore, with parts having leads, if a small amount of Pb is mixed into the solder from plating, the liftoff phenomenon sometimes occurs. Zn is a base metal, so Sn—Zn based alloys have the problem that when they are formed into a solder paste, changes occur with the passage of time, application can no longer take place by printing, and electrical corrosion takes place between soldered portions after soldering.

Accordingly, as lead-free solders having Sn as a main component, Sn—Ag based solders are superior to other binary lead-free solders from the standpoints of mechanical properties and melting point, and Sn—Ag—Cu solders having Cu added to Sn—Ag solders are much used.

Mounting of a BGA or the like is usually carried out by a process in which a solder paste comprising a solder alloy powder such as a Sn—Ag—Cu alloy powder and a flux is printed on a mounting board, an electronic part having bumps made of a Sn—Ag—Cu based solder alloy formed on a BGA or the like is mounted on the mounting board, and heating and melting are carried out to perform soldering.

### DISCLOSURE OF INVENTION

### Problem Which the Invention is to Solve

Recently in this process, even if mounting is carried out at a temperature sufficiently exceeding the melting point of the solder alloy, the fusion defect phenomenon in which solder bumps of a module board of a CSP, BGA, or the like and solder paste or parts having leads and solder paste do not fuse and conduction defects occur is becoming a problem. This leads not only to the occurrence of conduction defects but also to electronic equipment being unable to satisfy its function, and in some cases, there is the possibility of the problem resulting in claims for damages. In contrast to soldering of chip parts (which undergo little warping) to rigid printed wiring boards, soldering of a module board to a rigid printed wiring board is characterized in that a module board and a rigid printed wiring board both develop a large amount of warping when heated together during reflow. This phenomenon was ascertained before the electrodes of parts became lead-free, but it has been more frequently ascertained as electrodes of parts have become lead-free, and there is an urgent need for countermeasures with respect to electrodes using lead-free solder, which are becoming standard.

The main cause of the fusion defects phenomenon is the influence of corrosion on the surface of solder bumps of module boards such as those of BGA's and warping of substrates and parts. In particular, when the surface of solder bumps is not adequately cleaned of flux used at the time of bump formation or when parts are exposed to a high temperature and a high humidity, a strong oxide film forms on the surface of bumps. In the past, cleaning the oxide film on the surface was performed by the flux in a solder paste printed on a rigid printed wiring board in a surface mounting process. However, a surface oxide film like that described above is strong and its surface is not easily reduced, and when warping of the substrate and parts develops at the time of heating and mounting, the printed solder paste and the solder bumps of the parts sometimes separate from each other, and the possibility of fusion defects increases. According to market reports, the rate of occurrence of such defects is on the ppm level, but when an experiment was carried out in which a ball surface is exposed to a high temperature and high humidity which produce corrosion, it was ascertained that the rate of occurrence reaches a level of 50-70%.

As a countermeasure against fusion defects, it is conceivable to eliminate warping which develops in parts and mounting substrates or to increase the activity of solder paste. However, under current technology, it is impossible from a practical standpoint to eliminate warping of a substrate, and increasing the activity of a flux in a solder paste promotes a reaction with solder powder, and from the standpoint of changes with the passage of time, there is the possibility of its worsening the reliability of paste. Therefore, it was not an effective countermeasure against fusion defects.

### Means for Solving the Problem

The present inventors conducted diligent investigations concerning a method of preventing the occurrence of fusion defects at the time of mounting electronic parts having electrodes of a lead-free solder with Sn as a main component. As a result, they found that by previously applying a post-flux to solder bumps of a module board for a BGA or the like, the rate of occurrence of these fusion defects is decreased, and they thereby completed the present invention.

The present invention is a method of soldering a module board in which a post-flux is previously applied to solder bumps of a module board before mounting with respect to solder bumps of a module board, a solder paste is then applied, and the module board is soldered.

As stated above, possible countermeasures against the fusion defect phenomenon at the time of mounting module boards having electrodes of a lead-free solder having Sn as a main component include the following:

1. using a printed wiring board having a high Tg value such that there is no warping at the time of heating,

2. adding a large amount of active components to a solder paste and increasing its activity as much as possible, and

3. using N₂ reflow having a low oxygen content.

However, these countermeasures have problems such as the following.

Countermeasure 1 has the problem that a printed wiring board having a high Tg value which eliminates warping at the time of heating has not been developed.

Countermeasure 2 is not desirable from the standpoint of reliability such as with respect to corrosion of electronic parts and printed circuit boards.

Countermeasure 3 increases equipment costs and running costs.

As a result, the soldering method of the present invention was developed as a method which is of low cost and high reliability and easily carried out.

According to the findings of the present inventors, the mechanism of a countermeasure according to the present invention against fusion defects at the time of mounting electronic parts having electrodes of a lead-free solder is as follows.

1. With an ideal printed wiring board having no warping at the time of heating, the flux in solder paste completely spreads over the surface of solder bumps and portions to be soldered are completely covered. However, such a printed wiring board has not actually been developed. A module board and a rigid printed wiring board each develop warping, so soldered portions are not completely covered by a flux of the solder paste.

2. If a post-flux is previously applied to solder bumps of a module board, the portions to be soldered are already completely covered with flux, so during heating, an oxide film and a corrosive film on the rigid printed wiring board are completely reduced and melted. This provides preparation for initiating a metal reaction.

3. If a post-flux is previously applied to solder bumps of a module board, the wetting speed of solder is increased, and the solder is completely wet before warping of the substrate by heating at the time of reflow. As a result, problems do not readily occur at the time of mounting.

### EFFECTS OF THE INVENTION

By using a soldering method according to the present invention, fusion defects, in which the solder bumps of a module board for a CSP, a BGA, or the like and solder paste do not fuse or in which parts having leads and solder paste do not fuse and conduction problems occur, do not take place, and it is possible to obtain soldered portions of high reliability.

### BEST MODE FOR CARRYING OUT THE INVENTION

A post-flux used in the present invention has a rosin-based resin as a main component. Post-fluxes include inorganic fluxes comprising a halogenated metal salt and water-soluble fluxes using a water soluble resin, but these dissociate in the presence of water and produce corrosion of electronic parts and substrates. With a rosin-based flux used in the present invention, rosin has the effect of isolating water from corrosive substances. Therefore, corrosion does not take place even under conditions in which water is present such as at a high temperature and high humidity. This effect is exhibited when the surface conditions of solder bumps of module boards have become more severe.

A post-flux used in the present invention has the object of providing an activating effect with respect to solder bumps. Therefore, if necessary, it preferably contains an activator such as a hydrohalide or an organic acid. Because it is necessary to uniformly apply the post-flux to a solder bump, it contains a suitable solvent in accordance with the work environment.

Depending on the purpose of use, flux has been categorized as preflux used for protecting a printed circuit board prior to soldering and post-flux used for soldering of printed circuit boards. A preflux is applied to prevent surface deterioration of connecting portions in the form of Cu electrodes, and during a soldering process, it does not have an effect of removing an oxide film on connecting portions. Therefore, even if it is applied to the surface of solder bumps of a BGA or the like, it does not have an effect of reducing an oxide film.

Namely, a preflux is for the purpose of protection such as preventing oxidation of the surface of a substrate, and it does not contain an activator such as a hydrohalide or an organic acid. In addition, a solder bump plated with solder has an effect of preventing surface oxidation. Therefore, it has not been conceived of also using a preflux atop solder plating.

In the present invention, flux is applied to solder bumps with the object of removing an oxide film on the solder bump surface by a reducing action. Therefore, the effect is different from the effect of a preflux which acts as a rust preventer.

### Examples

After solder bumps were formed on a module board (CSP substrate), a load of high temperature, high humidity conditions of 85 degrees C. and 85% RH was applied in a storage step to prepare samples which could easily develop fusion defects. Prior to mounting, a flux was applied to the solder bumps of a portion of the samples and dried in hot air. In a mounting machine, a solder paste was applied to the module boards, the module board was mounted on a mounting substrate, and the solder paste was heated and melted in a reflow furnace. The details of the test method are described below. The test results are shown in Table 1.

TABLE 1

| | | | Flux | | Occurrence |
|---|---|---|---|---|---|
| | Storage | Oxide film | | Application | of fusion |
| | conditions | thickness (nm) | Presence | method | defects (%) |
| Example 1 | 85° C., 85% | 34 | liquid (15% | spraying | 0 |
| | RH for 72 | | solids content) | | |
| | hours | | | | |
| Example 2 | 85° C., 85% | 34 | liquid (9% | spraying | 0 |
| | RH for 72 | | solids content) | | |
| | hours | | | | |
| Example 3 | 85° C., 85% | 34 | liquid (35% | brush | 0 |
| | RH for 72 | | solids content) | application | |
| | hours | | | | |
| Example 4 | 85° C., 85% | 34 | Paste | transfer | 0 |
| | RH for 72 | | | | |
| | hours | | | | |
| Example 5 | 85° C., 85% | 46 | liquid | brush | 0 |
| | RH for 96 | | (containing an | application | |
| | hours | | activator) | | |
| Comparative | vacuum | 7 | none | — | 0 |
| Example 1 | storage | | | | |
| Comparative | 85° C., 85% | 28 | none | — | 5 |
| Example 2 | RH for 24 | | | | |
| | hours | | | | |
| Comparative | 85° C., 85% | 32 | none | — | 14 |
| Example 3 | RH for 48 | | | | |
| | hours | | | | |
| Comparative | 85° C., 85% | 34 | none | — | 76 |
| Example 4 | RH for 72 | | | | |
| | hours | | | | |

1. Test of occurrence of unfused portions: After the formation of solder bumps, a CSP substrate which was exposed to different storage conditions (while incorporated into a series circuit) was mounted on a rigid printed wiring board (FR-4), and heating was performed to carry out melting. It was determined that the solder had melted and fused in a normal manner when electrical conduction was ascertained. The process of the test was as follows.

### (Test Procedure)

1. Flux was printed on a CSP substrate measuring 8×8 mm and having 96 electrodes, and solder balls having a diameter of 0.3 mm were mounted on it.

2. The CSP substrate having the solder balls mounted on it was heated in a reflow furnace to form solder bumps on the electrodes.

3. The CSP substrate having solder bumps formed on it was left at a high temperature and high humidity, at a high temperature, or in a vacuum vessel.

4. The above-described samples were divided into ones having a flux applied to the bump surface, ones having solder paste applied, and ones which were untreated.

5. The above-described samples of CSP substrates were mounted on rigid printed wiring boards measuring 170×142×0.8 (mm), they were heated in a reflow furnace, and the CSP substrates were soldered to the rigid printed wiring boards.

6. The soldered rigid printed wiring boards for which the value of resistance passing through the CSP substrate was confirmed were determined to be good, and the number thereof was counted.

7. The number of good samples was subtracted from the total of 200, and the result was divided by the total number measured to calculate the rate of defects.

Each category in Table 1 was as follows.

1. Storage conditions: the conditions of applying a humidity load in a constant temperature, constant humidity bath and the length.

2. Oxide film thickness: the average thickness film of an oxide film under each condition measured using an x-ray photoelectron spectrometer (XPS)

3. Flux: the type of resin-based flux and the coating method.

4. Rate of occurrence of fusion defects: the number of occurrences of fusion defects divided by the total number of measured samples and expressed as a percent.

FIG. 1 shows an example in which there was no occurrence of fusion defects when a module board was oxidized under the storage conditions of Example 3 of 85 degrees C. and 85% RH for 72 hours and then underwent post-flux treatment. FIG. 2 shows an example in which fusion defects occurred when post-flux treatment was not carried out after a module board was oxidized under the storage conditions of Comparative Example 4 of 85 degrees C. and 85% RH for 72 hours.

The examples of module boards of this invention which had post-flux previously applied to them did not experience fusion defects when soldered to a rigid printed wiring board, but the comparative examples of module boards to which a post-flux was not applied experienced fusion defects.

### BRIEF EXPLANATION OF THE DRAWINGS

FIG. 1—This shows Example 3 for which fusion defects did not occur.

FIG. 2—This shows Comparative Example 4 for which fusion defects occurred.

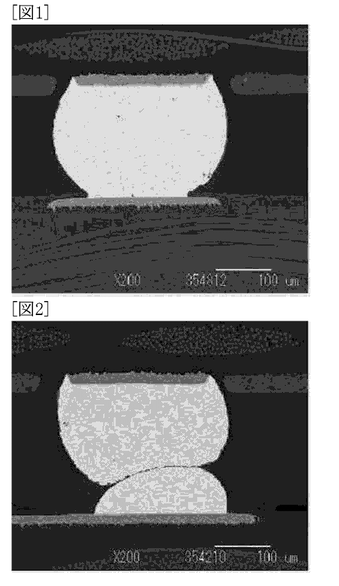

### INDUSTRIAL APPLICABILITY

A method of suppressing fusion defects by application of a resin-based flux according to the present invention is not limited to parts without leads, and it is thought that it can cope with fusion defects in parts with leads such as LGA's (land grid arrays), SOP's (small outline package), and QFP's (quad flat packages).

A resin-based flux which is applied can be in the form of a solder paste formed by mixing a paste flux and a solder alloy powder.

Suitable methods of applying an appropriate amount of flux include, a method in which the flux is previously applied to the bump surface by spraying or with a brush in accordance with the solids content in the case of a liquid flux and a method of application by transfer in the case of a paste.

1-4. (canceled)

5. A method of soldering a module board to a rigid printed wiring board comprising applying a liquid post-flux to solder bumps formed on the module board, then disposing the module board atop a rigid printed wiring board having a solder paste applied thereto, and then heating the module board and the rigid printed wiring board.

6. A method of soldering a module board as claimed in claim 5 including forming the solder bumps on the module board from solder balls.

7. A method of soldering a module board as claimed in claim 5 wherein the liquid post-flux comprises a rosin, an activator, and a solvent.

8. A printed circuit board manufactured by the method of claim 5.
